(19) United States
(12) Patent Application Publication
(10) Pub. No.: US 2013/0249714 A1
(43) Pub. Date: Sep. 26, 2013

(54) KEYPAD MODULE AND DETECTING METHOD FOR KEYPAD MATRIX

(71) Applicant: Chia-Chu HO, Taoyuan County (TW)

(72) Inventor: Chia-Chu HO, Taoyuan County (TW)

(21) Appl. No.: 13/425,074

(22) Filed: Mar. 20, 2012

(51) Int. Cl. H03M 11/00

(52) U.S. Cl. 341/22

(57) ABSTRACT

A keypad module is provided. The keypad module includes a keypad matrix, a plurality of resistors, a pull-up resistor and a controller coupled to the keypad matrix. The keypad matrix comprises a plurality of keys disposed in intersections of a plurality of first lines and a plurality of second lines. Each of the resistors is coupled between an individual line of the second lines and a common node. The pull-up resistor is coupled to the common node. The controller provides a low logic level signal to the first lines of the keypad matrix and obtains a trigger event via the common node when one of the keys is pressed in the keypad matrix.

### BACKGROUND OF THE INVENTION

1. Field of the Invention

The invention relates to a keypad module, and more particularly to a keypad module capable of performing trigger-driven key scanning operation.

2. Description of the Related Art

Keypad modules are widely used in portable devices, such as mobile phones. One keypad scanning technique uses a processor to periodically poll (typically every 20-30 milliseconds) the state of a keypad matrix of a keypad module, so as to determine when a key is pressed or released. However, polling more frequently may result in power consumption and excess keypad strobe noise, while polling less frequently may result in the missing of keypresses and keyreleases.

Another keypad scanning technique uses interrupts to a controller, to indicate whether any key of a keypad module has been pressed. The interrupts may be a specific event for waking up the controller when the controller is operated in an idle mode or sleep mode. In general, actual number of interrupt/wake-up IO pins (or ports) of the controller depend on the number of columns or rows in a keypad matrix of the keypad module. In the controller, the number of interrupt sources and corresponding connections are increased when the number of rows or columns of the keypad matrix is increased, thus occupying interrupt/wake-up resources of the controller. However, the interrupt/wake-up resources are limited for the controller. If the interrupt/wake-up resources of the controller are not enough to support the keypad matrix, an additional controller is needed for performing key scanning operations.

Less interrupt sources are desired for a keypad matrix in a keypad module, so as to decrease costs and board space of the keypad module.

### BRIEF SUMMARY OF THE INVENTION

Keypad module and a detecting method for a keypad matrix are provided. An embodiment of a keypad module is provided. The keypad module comprises a keypad matrix, a plurality of resistors, a pull-up resistor and a controller coupled to the keypad matrix. The keypad matrix comprises a plurality of keys disposed in intersections of a plurality of first lines and a plurality of second lines. Each of the resistors is coupled between an individual line of the second lines and a common node. The pull-up resistor is coupled to the common node. The controller provides a low logic level signal to the first lines of the keypad matrix and obtains a trigger event via the common node when one of the keys is pressed in the keypad matrix.

Furthermore, an embodiment of a detecting method for a keypad matrix is provided. The keypad matrix comprises a plurality of keys disposed in intersections of a plurality of first lines and a plurality of second lines, and each of the second lines is coupled to a common node via an individual resistor. A low logic level signal is provided to the first lines of the keypad matrix. A trigger event is obtained via the common node when one of the keys is pressed in the keypad matrix. A pull-up resistor is coupled to the common node.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a keypad module according to an embodiment of the invention;

FIG. 2 shows a detecting method for a keypad matrix according to an embodiment of the invention; and

FIG. 3 shows an example illustrating a waveform diagram of the keypad module of FIG. 1.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

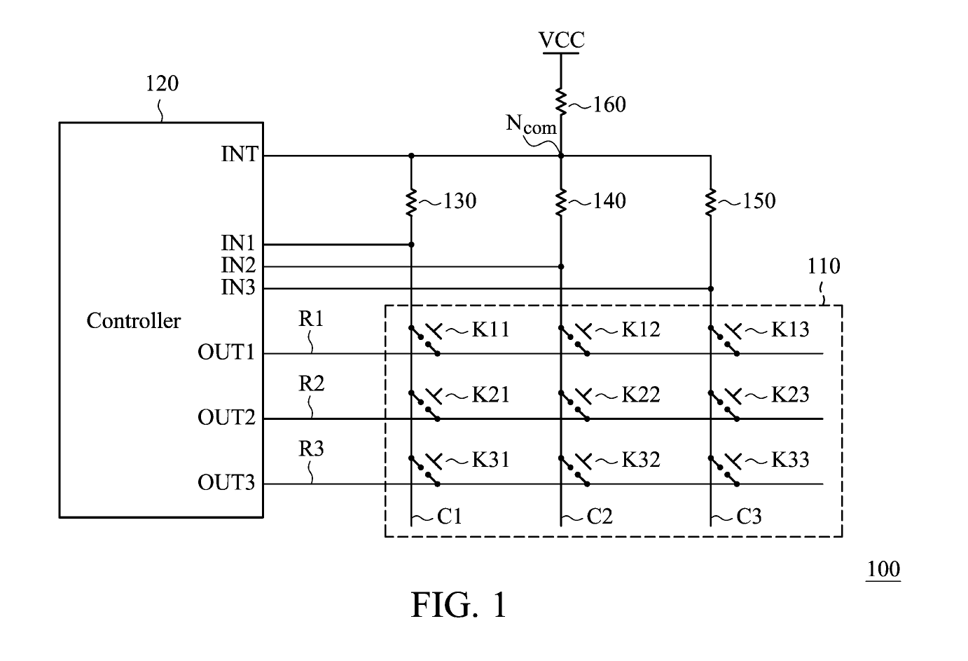

FIG. 1 shows a keypad module 100 according to an embodiment of the invention. The keypad module 100 comprises a keypad matrix 110, a controller 120 and the resistors 130, 140, 150 and 160. The keypad matrix 110 comprises the keys K11, K12, K13, K21, K22, K23, K31, K32 and K33 disposed in intersections of the row lines R1-R3 and the column lines C1-C3. For example, the key K11 is arranged in the intersection of the row line R1 and the column line C1, and the key K33 is arranged in the intersection of the row line R3 and the column line C3. In the embodiment, the keypad matrix 110 comprising 3×3 keys is used as an example for description, and does not limit the invention. The output pins OUT1-OUT3 of the controller 120 are coupled to the row lines R1-R3 of the keypad matrix 110, respectively. The input pins 1N1-1N3 of the controller 120 are coupled to the column lines C1-C3 of the keypad matrix 110, respectively. The connections of the input and output pins of the controller 120 are used as an example, and do not limit the invention. In one embodiment, the input pins IN1-IN3 and the output pins OUT1-OUT3 of the controller 120 are coupled to the column lines C1-C3 and the row lines R1-R3 of a keypad matrix, respectively. Furthermore, a bi-directional pin INT of the controller 120 is coupled to a common node N_{com}. In the embodiment, the bi-directional pin INT is an interrupt/wake-up resource of the controller 120. The resistor 130 is coupled between the input pin IN1 of the controller 120 and the common node N_{com}. The resistor 140 is coupled between the input pin IN2 of the controller 120 and the common node N_{com}. The resistor 150 is coupled between the input pin IN3 of the controller 120 and the common node N_{com}. The resistor 160 is a pull-up resistor coupled between the common node N_{com} and a power supply VCC. In the embodiment, the resistors 130, 140 and 150 have the same resistances smaller than that of the resistor 160. Furthermore, the keypad module 100 can be implemented in a portable device, wherein the controller 120 can be implemented in an integrated circuit of the portable device, and the bi-directional pin INT is used to receive a wake up event or an interrupt event for the integrated circuit.

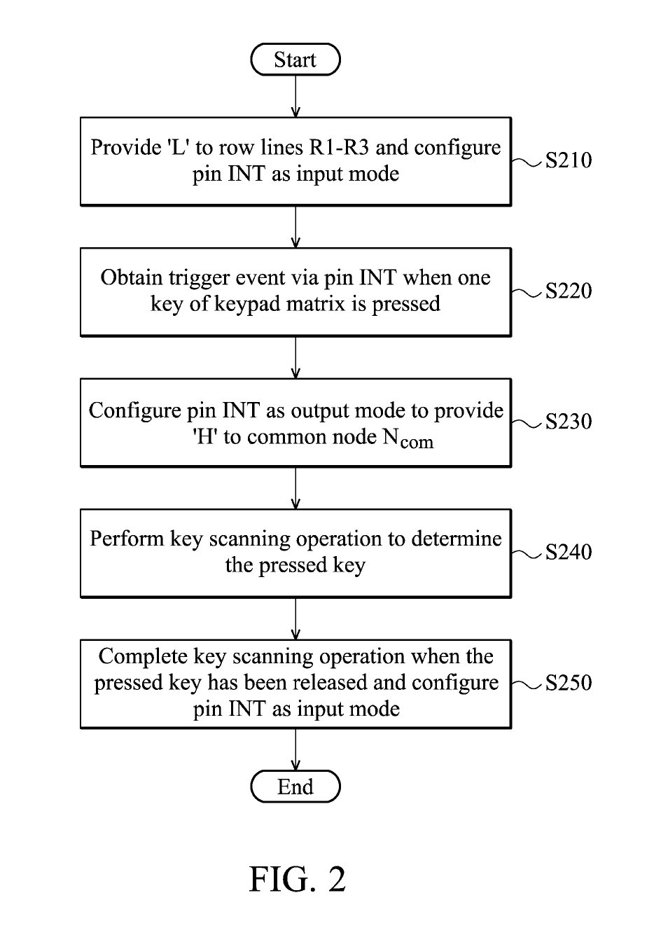

FIG. 2 shows a detecting method for a keypad matrix according to an embodiment of the invention. Referring to FIG. 1 and FIG. 2 together, in step S210, the controller 120 simultaneously provides a low logic level signal to the row lines R1-R3 via the output pins OUT1-OUTS and configures the bi-directional pin INT as an input mode for detecting a voltage of the common node N_{com}. If no key of the keypad matrix 110 is pressed, the voltage of the common node N_{com} is pulled up to a high logic level ‘H’ via the resistor 160. Once any key of the keypad matrix 110 is pressed, the voltage of the common node N_{com} is changed from a high logic level ‘H’ to a low logic level ‘L’, and the controller 120 obtains a trigger event via the bi-directional pin INT (step S220). The trigger event may be an interrupt event or a wake-up event. Next, in step S230, the controller 120 configures the bi-directional pin INT as an output mode for providing a high logic level signal ‘H’ to the common node N_{com}. Next, in step S240, the controller 120 performs a key scanning operation via the output pins OUT1-OUT3 and the input pins IN1-IN3, to determine the pressed key. For example, the controller 120 may select one of the row lines to toggle and obtain the variations of the column lines in response to the toggle of the selected row line. After the pressed key is determined, the controller 120 further detects whether the pressed key has been released. When the pressed key has been released or no key is pressed, the controller 120 completes the key scanning operation, and configures the bi-directional pin INT as an input mode to wait for a next trigger event (step S250). In the embodiment, only one interrupt/wake-up resource (e.g. the bi-directional pin INT) is needed for the controller 120, thus decreasing cost and board space of the keypad module 100.

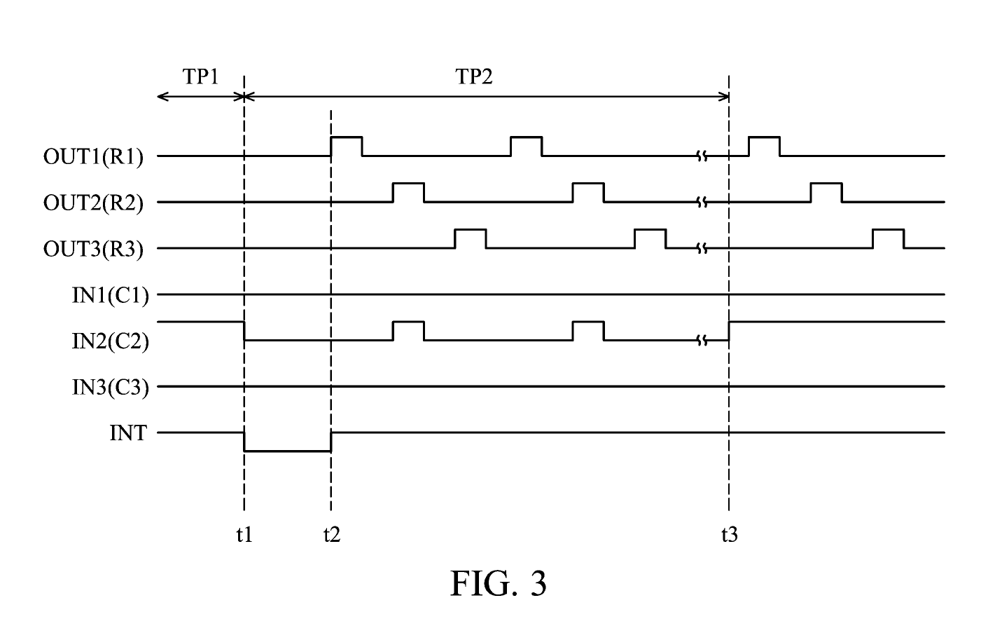

FIG. 3 shows an example illustrating a waveform diagram of the keypad module 100 of FIG. 1. Referring to FIG. 1 and FIG. 3 together, the controller 120 provides a low logic level signal to the row lines R1-R3 via the output pins OUT1-OUT3 during a time period TP1. Simultaneously, the controller 120 configures the bi-directional pin INT as an input mode for receiving the voltage of the common node N_{com}. Because no key is pressed during the time period TP1, the voltage of the common node N_{com} and the voltages of the column lines C1-C3 are pulled to a low logic level ‘H’ by the power supply VCC and the pull-up resistor 160. Assuming that the key K22 is pressed during a time period TP2 in FIG. 3, the key K22 is arranged in the intersection of the row line R2 and the column line C2 of the keypad matrix 110, thereby the row line R2 is connected to the column line C2 via the pressed key K22 at time t1. Thus, the column line C2 is pulled down by the row line R2, and then the voltage of the common node N_{com} is also pulled down, i.e. the voltage of the common node Nₑₒₙ, is changed from a high logic level ‘H’ to a low logic level ‘L’. In response to the voltage variation at the common node N_{com}, the controller 120 obtains a trigger event at time t1. Furthermore, the controller 120 further detects that one of the column lines (i.e. C2) is pulled down. Next, the controller 120 starts to perform a key scanning operation at time t2. The controller 120 may periodically toggle the row lines R1-R3 via the output pins OUT1-OUT3 in the key scanning operation. When the row line R2 is toggled, the controller 120 detects a voltage variation corresponding to the toggle in the column line C2. Therefore, it is determined that the key K22 has been pressed. Next, the pressed key K22 is released at time t3, thereby the column line C2 is changed from a low logic level ‘L’ to a high logic level ‘H’. When detecting that all of the column lines are pulled up to a high logic level ‘H’, i.e. no key is pressed, the controller 120 completes the key scanning operation and configures the bi-directional pin INT as an input mode, so as to obtain a next trigger event.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A keypad module, comprising:
a keypad matrix, comprising a plurality of keys disposed in intersections of a plurality of first lines and a plurality of second lines;
a plurality of resistors, wherein each of the resistors is coupled between an individual line of the second lines and a common node;
a pull-up resistor coupled to the common node; and
a controller coupled to the keypad matrix, providing a low logic level signal to the first lines of the keypad matrix and obtaining a trigger event via the common node when one of the keys is pressed in the keypad matrix.

2. The keypad module as claimed in claim 1, wherein the controller obtains the trigger event when a voltage of the common node is changed from a high logic level to a low logic level.

3. The keypad module as claimed in claim 1, wherein when the trigger event is obtained, the controller provides a high logic level signal to the common node and performs a key scanning operation via the first and second lines to determine the pressed key.

4. The keypad module as claimed in claim 3, wherein the controller further detects whether the pressed key has been released, and when the pressed key has been released, the controller completes the key scanning operation and stops providing the high logic level signal to the common node.

5. The keypad module as claimed in claim 3, wherein the controller provides a first signal to the first lines and receives a second signal from the second lines in response to the first signal in the key scanning operation, so as to determine the pressed key according to the second signal.

6. The keypad module as claimed in claim 1, wherein the first and second lines are the row and column lines of the keypad matrix, respectively.

7. The keypad module as claimed in claim 1, wherein the first and second lines are the column and row lines of the keypad matrix, respectively.

8. The keypad module as claimed in claim 1, wherein the controller is implemented in an integrated circuit, and the integrated circuit comprises a plurality of output pins coupled to the first lines, a plurality of input pins coupled to the second lines and a bi-directional pin coupled to the common node.

9. The keypad module as claimed in claim 1, wherein the trigger event is a wake up event or an interrupt event for the integrated circuit.

10. The keypad module as claimed in claim 1, wherein the resistors have the same resistance smaller than that of the pull-up resistor.

11. A detecting method for a keypad matrix, wherein the keypad matrix comprises a plurality of keys disposed in intersections of a plurality of first lines and a plurality of second lines, and each of the second lines is coupled to a common node via an individual resistor, the detecting method comprising:
providing a low logic level signal to the first lines of the keypad matrix; and
obtaining a trigger event via the common node when one of the keys is pressed in the keypad matrix,
wherein a pull-up resistor is coupled to the common node.

12. The detecting method as claimed in claim 11, wherein the trigger event is obtained when a voltage of the common node is changed from a high logic level to a low logic level.

13. The detecting method as claimed in claim 11, further comprising:
providing a high logic level signal to the common node when the trigger event is obtained; and
performing a key scanning operation via the first and second lines to determine the pressed key when the high logic level signal is provided to the common node.

14. The detecting method as claimed in claim 13, further comprising:
detecting whether the pressed key has been released; and
completing the key scanning operation to stop providing the high logic level signal to the common node when the pressed key has been released.

15. The detecting method as claimed in claim 13, wherein the step of performing the key scanning operation via the first and second lines to determine the pressed key when the high logic level signal is provided to the common node further comprises:
providing a first signal to the first lines;
receiving a second signal from the second lines in response to the first signal; and
determining the pressed key according to the second signal.

16. The detecting method as claimed in claim 11, wherein the first and second lines are the row and column lines of the keypad matrix, respectively.

17. The detecting method as claimed in claim 11, wherein the first and second lines are the column and row lines of the keypad matrix, respectively.

18. The detecting method as claimed in claim 11, wherein the individual resistors have the same resistance smaller than that of the pull-up resistor.
